(19) United States
(12) Patent Application Publication
(10) Pub. No.: US 2026/0005488 A1
(43) Pub. Date: Jan. 1, 2026

(54) OPTICAL SEMICONDUCTOR DEVICE

(71) Applicant: Mitsubishi Electric Corporation, Tokyo (JP)

(72) Inventor: Shinya OKUDA, Tokyo (JP)

(73) Assignee: Mitsubishi Electric Corporation, Tokyo (JP)

(21) Appl. No.: 18/993,108

(22) PCT Filed: Sep. 27, 2022
(86) PCT No.: PCT/JP2022/035944

§ 371 Date: Jan. 10, 2025

(51) Int. Cl. H01S 5/026; H01S 5/12; H01S 5/22; H01S 5/343

(52) U.S. Cl. CPC H01S 5/0265; H01S 5/12; H01S 5/22; H01S 5/34346

(57) ABSTRACT

An optical semiconductor device according to the present disclosure having a semiconductor laser section and an optical modulator section formed above a common semiconductor substrate, comprising: the semiconductor laser section including: a first-conductivity-type lower cladding layer; an active layer configured to emit laser light; and a second-conductivity-type upper cladding layer provided with a first-order diffraction grating, which are each made of a group III-V semiconductor compound crystal; and the optical modulator section including: a light absorption layer configured to absorb the laser light incident from the active layer, at least a part of the light absorption layer made of a group III-V semiconductor compound crystal containing Bi; and a scattered-light absorption layer that faces either a lower surface or an upper surface of the light absorption layer, or a pair of scattered-light absorption layers that face the lower surface and the upper surface of the light absorption layer, respectively.

### TECHNICAL FIELD

The present disclosure relates to an optical semiconductor device.

### BACKGROUND ART

In recent years, the spread of various information terminals and the shift to cloud computing have led to a rapid increase in data traffic. In order to meet the demand for increased data traffic, the transmission speeds and capacities of optical fiber communication base stations are being increased.

As a light source for long-distance optical communication in optical fiber communication, a semiconductor laser device with an optical modulator (Electro-absorption Modulator Laser Diode: EML-LD), which is a kind of optical semiconductor device and in which a semiconductor laser section and an optical modulator section are monolithically integrated, is used. The optical modulator is a type of external modulator that allows high-speed, long-distance optical fiber transmission with less signal waveform degradation than direct modulation, which directly modulates the laser light intensity.

In the EML-LD, at a coupling section (butt joint) between the semiconductor laser section composed of a distributed feedback laser diode (DFB-LD) and the optical modulator section composed of an electro-absorption modulator (EML), scattered light that is not guided to the optical absorption layer of the optical modulator section in the laser light incident from the semiconductor laser section is emitted to the outside from the output end surface of the optical modulator section and becomes leakage light. The leakage light appears as a side peak of the output light, hindering the optical axis adjustment of the EML-LD and causing a decrease in the extinction ratio, that is, the light intensity ratio in the on/off state of the light. As the EML-LD operates at a higher output, the intensity of the leakage light emitted from the EML-LD to the outside increases, resulting in a problem that the extinction ratio further decreases.

### CITATION LIST

### Patent Document

Patent Document 1: Japanese Laid-Open Patent Publication No. 03-77386

### SUMMARY OF THE INVENTION

### Problem to be Solved by the Invention

In order to prevent the decrease in the extinction ratio of the EML-LD, for example, the semiconductor light-emitting device described in Patent Document 1 has a light-shielding film with an opening in the end surface of the light absorption layer on the output end surface of the optical modulator section.

The shielding film provided on the optical modulator section of the semiconductor light-emitting device disclosed in Patent Document 1 functions to shield leakage light output from the output end surface other than that of the light absorption layer. The shielding film enables leakage light to be securely shielded on the output end surface of the optical modulator section, thus providing an effect of increasing the extinction ratio during optical modulation.

In order to provide the shielding film on the output end surface of the optical modulator section, it is necessary to form a metal film on the entire output end surface, and then to mask the portion other than the opening and remove the metal film by ion etching or the like. Unfortunately, the processing on the output end surface is extremely difficult, so it is difficult to maintain the processing accuracy required for the shielding film. Consequently, there is a problem in producing an optical semiconductor device with small leakage light, that is, a high extinction ratio, with good reproducibility.

The present disclosure has been made to solve the above problem, and an object of the present disclosure is to provide an optical semiconductor device having a high extinction ratio even during high-power operation.

### Means to Solve the Problem

An optical semiconductor device according to the present disclosure having a semiconductor laser section and an optical modulator section formed above a common semiconductor substrate, the optical semiconductor device comprises: the semiconductor laser section including: a first-conductivity-type lower cladding layer; an active layer configured to emit laser light; and a second-conductivity-type upper cladding layer provided with a first-order diffraction grating, the lower cladding layer, the active layer and the upper cladding layer being each made of a group III-V semiconductor compound crystal; and the optical modulator section including: a light absorption layer configured to absorb the laser light incident from the active layer, at least a part of the light absorption layer made of a group III-V semiconductor compound crystal containing Bi; and a scattered-light absorption layer that faces either a lower surface or an upper surface of the light absorption layer, or a pair of scattered-light absorption layers that face the lower surface and the upper surface of the light absorption layer, respectively.

### Effect of the Invention

In the optical semiconductor device according to the present disclosure, since the scattered-light absorption layer provided in the optical modulator section absorbs the scattered light other than the guided light guided by the optical absorption layer, it is possible to prevent a decrease in the extinction ratio caused by the scattered light, and since the light absorption layer contains Bi, it is possible to simultaneously suppress the decrease in the extinction ratio caused by the pile-up of holes in the optical absorption layer due to the heat generated by the absorption of the scattered light by the scattered-light absorption layer, thus providing an effect of achieving an optical semiconductor device having a high extinction ratio.

### BRIEF DESCRIPTION OF THE DRAWINGS

FIG. 1 is a cross-sectional view along the optical waveguide direction in an optical semiconductor device according to Embodiment 1;

FIG. 2 is a cross-sectional view in the direction perpendicular to the optical waveguide direction in the optical semiconductor device according to Embodiment 1;

FIG. 3 is a cross-sectional view showing the configuration of a light absorption layer of an optical modulator section in the optical semiconductor device according to Embodiment 1;

FIG. 4 is an energy band diagram of the optical modulator section in the optical semiconductor device according to Embodiment 1;

FIG. 5 is a cross-sectional view along the optical waveguide direction in an optical semiconductor device according to Embodiment 2;

FIG. 6 is a cross-sectional view showing the configuration of a light absorption layer of an optical modulator in the optical semiconductor device according to Embodiment 2;

FIG. 7 is an energy band diagram of the optical modulator in the optical semiconductor device according to Embodiment 2;

FIG. 8 is a cross-sectional view along the optical waveguide direction in an optical semiconductor device according to Embodiment 3;

FIG. 9 is a cross-sectional view in the direction perpendicular the optical waveguide direction in an optical semiconductor device according to Embodiment 4.

### DESCRIPTION OF EMBODIMENTS

### Embodiment 1

### Structure of Optical Semiconductor Device According to Embodiment 1

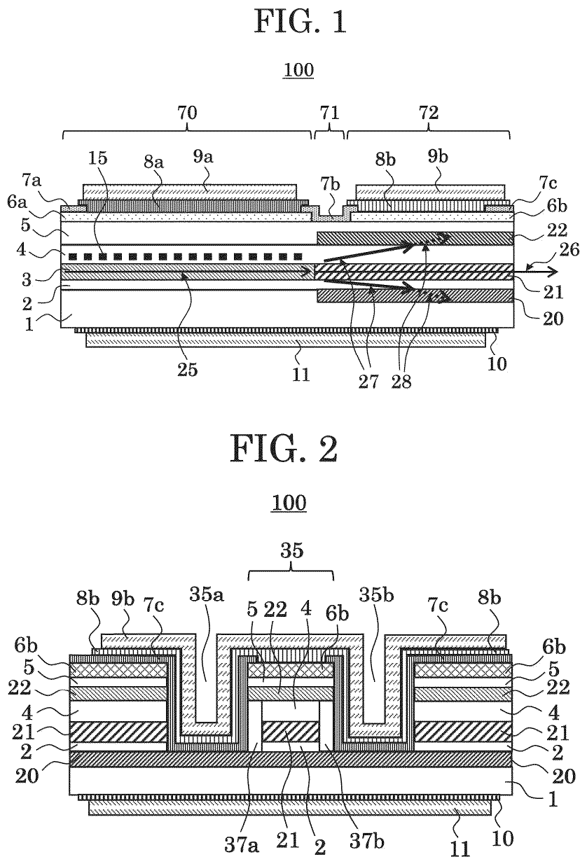

FIG. 1 is a cross-sectional view along the optical waveguide direction in an optical semiconductor device according to Embodiment 1. An EML-LD is given as an example of the optical semiconductor device 100 according to Embodiment 1.

The optical semiconductor device 100 according to Embodiment 1 comprises a semiconductor laser section 70, a separation section 71, and an optical modulator section 72. In the following description, the vertical direction is defined as follows: in a direction perpendicular to the surface of the semiconductor substrate, a direction toward the surface of the crystal growth layer with respect to the active layer or the light absorption layer is defined as an upward direction, and a direction toward the back surface of the semiconductor substrate is defined as a downward direction.

The semiconductor laser section 70 is composed of crystal growth layers that include: an n-type InP lower cladding layer 2 (first-conductivity-type lower cladding layer 2); the active layer 3; a p-type InP upper first cladding layer 4 (second-conductivity-type upper cladding layer 4); a p-type InP upper second cladding layer 5; and a p-type InGaAs first contact layer 6a, which are sequentially formed above an n-type InP substrate 1 (semiconductor substrate 1).

A first-order diffraction grating 15 is formed in the p-type InP upper first cladding layer 4. The active layer 3 is typically composed of an InGaAsP multiple quantum well structure.

A p-side first electrode 8a and a p-side second electrode 9a are respectively formed on the p-type InGaAs first contact layer 6a through an opening of a surface protection insulating film 7a. An n-side first electrode 10 and an n-side second electrode 11 are formed on the back side of the n-type InP substrate 1, respectively.

The optical modulator section 72 is composed of crystal growth layers that include: a lower scattered-light absorption layer 20; the n-type InP lower cladding layer 2; the light absorption layer 21 made of i-type InGaAsBi which is a group III-V semiconductor compound crystal containing Bi (bismuth); the p-type InP upper first cladding layer 4; an upper scattered-light absorption layer 22; the p-type InP upper second cladding layer 5; and a p-type InGaAs second contact layer 6b, which are sequentially formed above the n-type InP substrate 1. In the following description, each of the lower scattered-light absorption layer 20 and the upper scattered-light absorption layer 22 is sometimes simply referred to as a scattered-light absorption layer. Also, the lower scattered-light absorption layer 20 and the upper scattered-light absorption layer 22 are sometimes collectively referred to as a pair of scattered-light absorption layers.

A p-side third electrode 8b and a p-side fourth electrode 9b are formed on the p-type InGaAs second contact layer 6b through an opening of a surface protection insulating film 7c. An n-side first electrode 10 and an n-side second electrode 11 are formed on the back side of the n-type InP substrate 1.

The semiconductor laser section 70, the separation section 71, and the optical modulator section 72 are formed above the common n-type InP substrate 1. The n-side first electrode 10 and the n-side second electrode 11 are also integrally formed in the semiconductor laser section 70, the separation section 71, and the optical modulator section 72.

The separation section 71 has the same configuration as the optical modulator section 72 except that the p-type InGaAs second contact layer 6b is not provided, the surface thereof is covered with a surface protection insulating film 7b, and the p-side third electrode 8b and the p-side fourth electrode 9b are not provided.

FIG. 2 is a cross-sectional view of the optical modulator section 72 in the direction perpendicular to the optical waveguide direction in the optical semiconductor device 100 according to Embodiment 1.

The mesa stripe 35 is formed by a pair of mesa grooves 35a, 35b provided on both side surfaces thereof. The bottom and side surfaces of the mesa grooves 35a, 35b are covered with the surface protection insulating film 7c. In the mesa stripe 35, high-resistivity InP buried layers 37a, 37b are formed on both side surfaces of the light absorption layer 21 that is made of i-type InGaAsBi. An example of a semiconductor material constituting high-resistivity InP is semi-insulating InP doped with Fe (iron).

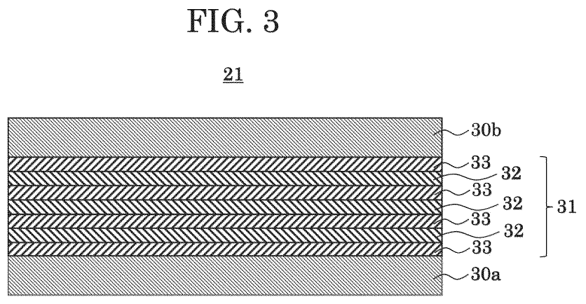

FIG. 3 is a cross-sectional view of an MQW layer 31 having a multiple quantum well structure constituting the light absorption layer 21 made of i-type InGaAsBi in the optical modulator section 72. The light absorption layer 21 made of i-type InGaAsBi includes: a lower SCH layer 30a; the MQW layer 31 in which well layers 32 and barrier layers 33 are alternately stacked; and an upper SCH layer 30b from the n-type InP substrate 1 side. MQW is an abbreviation of “Multi Quantum Well” and means a multiple quantum well. SCH is an abbreviation of “Separate Confinement Heterostructure” and means a separate confinement layer.

The well layers 32, the barrier layers 33, the lower SCH layer 30a and the upper SCH layer 30b are each composed of the group III-V semiconductor compound crystal containing Bi. Typical group III-V semiconductor compound crystal containing Bi is i-type InGaAsBi.

### Method for Manufacturing Optical Semiconductor Device According to Embodiment 1

An overview of a method for manufacturing the optical semiconductor device 100 according to Embodiment 1 will be described below.

First, a step of forming each crystal growth layer of the semiconductor laser section 70 will be described.

The n-type InP lower cladding layer 2, the active layer 3, and a part of the p-type InP upper first cladding layer 4 are sequentially epitaxially grown above the n-type InP substrate 1 in a region where the semiconductor laser section 70 is to be formed. Examples of the epitaxial crystal growth method include metal organic chemical vapor deposition (MOCVD) and molecular beam epitaxy (MBE).

After the epitaxial crystal growth described above, the first-order diffraction grating 15 is formed on the surface of the p-type InP upper first cladding layer 4 using photolithography and etching techniques. The remaining p-type InP upper first cladding layer 4, the p-type InP upper second cladding layer 5, and the p-type InGaAs first contact layer 6a are sequentially epitaxially grown by MOCVD or the like on the p-type InP upper first cladding layer 4 in which the diffraction grating 15 is formed. After the epitaxial crystal growth, an insulating film mask is patterned on the surface of the semiconductor laser section 70 using photolithography and etching techniques. For example, SiO₂ is preferable as a material for forming the insulating film mask.

Next, a step for forming the crystal growth layers of the separation section 71 and the optical modulator section 72 will be described. In the region above the n-type InP substrate 1 where the separation section 71 and the optical modulator section 72 are to be formed, the crystal growth layers of the lower scattered-light absorption layer 20, the n-type InP lower cladding layer 2, the light absorption layer 21 made of i-type InGaAsBi, the p-type InP upper first cladding layer 4, the upper scattered-light absorption layer 22, the p-type InP upper second cladding layer 5, and the p-type InGaAs second contact layer 6b are sequentially epitaxially grown by MOCVD or the like.

After the crystal growth layers of the separation section 71 and the optical modulator section 72 are formed, the insulating film mask covering the semiconductor laser section 70 is removed. Then, the region other than the region where the pair of mesa grooves 35a, 35b are to be formed is covered with the insulating film mask. For example, SiO₂ is preferable as a material for forming the insulating film mask.

Using the insulating film mask as an etching mask, a pair of mesa grooves 35a, 35b reaching from the p-type InGaAs first contact layer 6a, which is the topmost crystal growth layer, to the n-type InP substrate 1 in the semiconductor laser section 70, from the p-type InP upper second cladding layer 5, which is the topmost crystal growth layer, to the lower scattered-light absorption layer 20 in the separation section 71, and from the p-type InGaAs second contact layer 6b, which is the topmost crystal growth layer, to the lower scattered-light absorption layer 20 in the optical modulator section 72 are formed by an etching technique such as dry etching or wet etching.

After the formation of the pair of mesa grooves 35a, 35b, the high-resistivity InP buried layers 37a, 37b are crystal-grown by MOCVD or the like so as to be buried in the side surface portion on the side where the mesa stripe 35 is to be formed while the insulating film mask remains. After the buried crystal growth, unnecessary portions are removed by etching or the like to complete the mesa stripe 35.

An insulating film is formed so as to cover the entire crystal growth layers on the surface side of the EML-LD, and then openings are provided at the portions where the electrodes are to be formed using photolithography and etching techniques. The formed insulating film functions as the surface protection insulating films 7a, 7b, 7c. In the semiconductor laser section 70, the p-side first electrode 8a in contact with the p-type InGaAs first contact layer 6a through the opening of the surface protection insulating film 7a, and the p-side second electrode 9a on the p-side first electrode 8a are formed by electron beam evaporation or the like, and then patterned by lift-off.

The p-side third electrode 8b in contact with the p-type InGaAs second contact layer 6b through the opening of the surface protection insulating film 7c, and the p-side fourth electrode 9b on the p-side third electrode 8b are formed in the optical modulator section 72 by electron beam evaporation or the like, and then patterned by lift-off. Note that, the electrodes of the semiconductor laser section 70 and the optical modulator section 72 may be formed by the same step.

The n-side first electrode 10 and the n-side second electrode 11 are formed on the back surface side of the n-type InP substrate 1 by electron beam evaporation or the like, and then patterned by lift-off. The wafer is separated into individual chips by cleavage or the like, whereby the EML-LD is completed.

The above is an overview of the method for manufacturing the EML-LD, which is an example of the optical semiconductor device 100 according to Embodiment 1.

### Operation of Optical Semiconductor Device According to Embodiment 1

First, the basic operation of the EML-LD, which is an example of the optical semiconductor device 100 according to Embodiment 1, will be described below.

A current is injected into the semiconductor laser section 70 through the p-side first electrode 8a and the p-side second electrode 9a to emit laser light 25. Since the first-order diffraction grating 15 is provided in the p-type InP upper first cladding layer 4 adjacent to the active layer 3 of the semiconductor laser section 70, the semiconductor laser section 70 functions as a DFB-LD. Compared with a semiconductor laser having no diffraction grating, the DFB-LD has an advantage that the oscillation spectrum can be made into a single longitudinal mode.

The laser light 25 of the semiconductor laser section 70 enters the optical modulator section 72 through the separation section 71 as guided light 26. When a reverse bias voltage is applied from the outside such that the p-side third electrode 8b and the p-side fourth electrode 9b of the optical modulator section 72 are negative and the n-side first electrode 10 and the n-side second electrode 11 are positive, the absorption spectrum of the optical absorption layer 21 changes and thus a light absorption phenomenon occurs. The laser light 25 that enters the optical modulator section 72 from the semiconductor laser section 70 becomes the guided light 26. The guided light 26 is absorbed by the optical absorption layer 21 depending on the magnitude of the reverse bias voltage, thereby generating pairs of electrons and holes. When almost all of the guided light 26 is absorbed by the optical absorption layer 21 due to the light absorption phenomenon, the guided light 26 is extinguished. That is, the guided light 26 is not emitted from the output end surface of the optical modulator section 72. Based on the above operation principle, the intensity modulation of the laser light 25 can be achieved in the optical modulator section 72.

The above is the basic operation of the EML-LD.

Next, the characteristic operation of the EML-LD, which is an example of the optical semiconductor device 100 according to Embodiment 1, will be described below.

As described above, in the conventional EML-LD, in the coupling section (separation section) between the semiconductor laser section configured by the DFB-LD and the optical modulator section configured by the EML, the laser light incident from the semiconductor laser section and not guided to the light absorption layer of the optical modulator section becomes scattered light. The scattered light propagates through the optical modulator section, and then is emitted as leakage light from the output end surface of the optical modulator section to the outside. As the light output emitted by the EML-LD increases, the intensity of the leakage light emitted from the output end surface of the optical modulator section to the outside also increases in proportion, causing the extinction ratio to decrease even further.

In the EML-LD, which is an example of the optical semiconductor device 100 according to Embodiment 1, in order to prevent the extinction ratio from decreasing as the light output increases, the optical modulator section 72 is provided with the lower scattered-light absorption layer 20 and the upper scattered-light absorption layer 22 so as to face the lower surface of the light absorption layer 21, that is, the surface thereof on the n-type InP substrate 1 side, and the upper surface of the light absorption layer 21, that is, the surface thereof on the surface side of the crystal growth layer, respectively.

The lower scattered-light absorption layer 20 and the upper scattered-light absorption layer 22 function to absorb the scattered light 27 that is not guided to the light absorption layer 21 in the optical modulator section 72. That is, the scattered light 27 incident on the lower scattered-light absorption layer 20 and the upper scattered-light absorption layer 22 is absorbed as the absorbed light 28. Therefore, the leakage light emitted from the output end surface of the optical modulator section 72 to the outside can be greatly reduced, thus providing an effect of achieving a high extinction ratio.

The lower scattered-light absorption layer 20 and the upper scattered-light absorption layer 22 are composed of, for example, a group III-V quaternary semiconductor compound crystal such as InGaAsP having a layer thickness of several 100 nm and a bandgap energy similar to that of the active layer 3 of the semiconductor laser section 70. The lower scattered-light absorption layer 20 may be doped with an n-type impurity. The upper scattered-light absorption layer 22 may be doped with a p-type impurity.

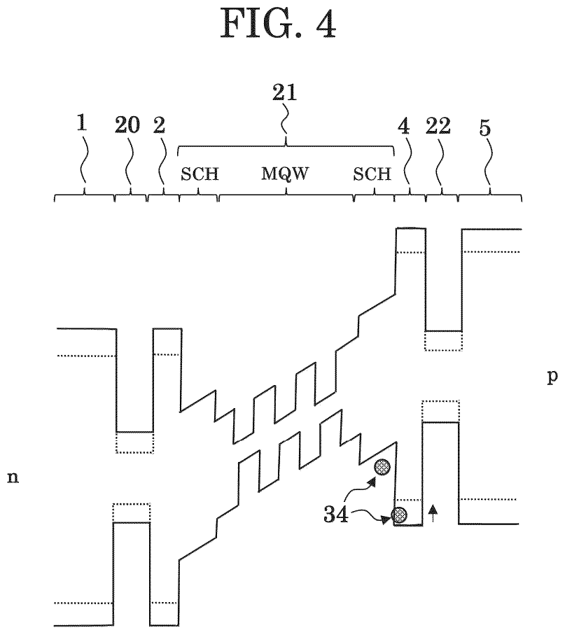

Next, the function of the light absorption layer 21 made of i-type InGaAsBi will be described. FIG. 4 is an energy band diagram of the optical modulator section 72. From the left side of FIG. 4, energy bands of the n-type InP substrate 1, the lower scattered-light absorption layer 20, the n-type InP lower cladding layer 2, the light absorption layer 21 made of i-type InGaAsBi, the p-type InP upper first cladding layer 4, the upper scattered-light absorption layer 22, and the p-type InP upper second cladding layer 5 are shown.

The energy band of the light absorption layer 21 made of i-type InGaAsBi is further composed of energy bands of the following layers: the lower SCH layer 30a containing Bi; the MQW layer 31 composed of four alternately stacked barrier layers 33 containing Bi and three well layers 32 containing Bi; and the upper SCH layer 30b containing Bi. Each well layer 32, each barrier layer 33, the lower SCH layer 30a, and the upper SCH layer 30b are made of i-type InGaAsBi. The bandgap energies of the lower SCH layer 30a and the upper SCH layer 30b are set to be larger than that of the barrier layer 33. The bandgap energy of the barrier layer 33 is set to be larger than that of the well layer 32.

The group III-V semiconductor compound crystal containing Bi have a smaller temperature dependence of the bandgap energy as the Bi content increases. In particular, InGaAsBi has a property that the bandgap (0.6 to 1.5 eV) becomes constant with respect to temperature changes. This means that the group III-V semiconductor compound crystal containing Bi have a smaller temperature dependence of the bandgap energy. Therefore, even if the temperature of the group III-V semiconductor compound crystal containing Bi increases, the degree of decrease in the bandgap energy due to temperature increase becomes significantly smaller that of the group III-V semiconductor compound crystal not containing Bi.

In the EML-LD, which is an example of the optical semiconductor device 100 according to Embodiment 1, as described above, the scattered light 27 incident on the lower scattered-light absorption layer 20 and the upper scattered-light absorption layer 22 is absorbed as the absorbed light 28. Heat is generated in the lower scattered-light absorption layer 20 and the upper scattered-light absorption layer 22 by absorption of the scattered light 27, and thus the heat spreads to each crystal growth layer constituting the optical modulator section 72, so that the temperature of the optical modulator section 72 increases.

As shown in the energy band represented by the dotted line in FIG. 4, the heat generated by the absorption of the scattered light 27 causes that each bandgap energy of the n-type InP substrate 1, the lower scattered-light absorption layer 20, the n-type InP lower cladding layer 2, the p-type InP upper first cladding layer 4, the upper scattered-light absorption layer 22, and the p-type InP upper second cladding layer 5 is smaller than the energy band in the case where no heat is generated, that is, the energy band represented by the solid line in FIG. 4.

On the other hand, since the light absorption layer 21 made of i-type InGaAsBi contains Bi as described above, the temperature dependence of the bandgap energy is small, so that the energy band almost does not change even with the heat generated by the absorption of the scattered light 27.

Therefore, the magnitude of the electron barrier ΔEc on the conduction band side and the magnitude of the hole barrier ΔEv on the valence band side are reduced due to the generation of heat. Here, the electron barrier ΔEc and the hole barrier ΔEv are band discontinuities generated between the p-type InP upper first cladding layer 4 and the upper SCH layer 30b that is part of the light absorption layer 21 made of i-type InGaAsBi and is in contact with the p-type InP upper first cladding layer 4. This is because the bandgap energy of the upper SCH layer 30b containing Bi almost does not change even with heat, while the bandgap energy of the p-type InP upper first cladding layer 4 decreases with heat.

Here, the hole pile-up phenomenon, which has a significant influence on the extinction ratio of the EML-LD, will be described. As the semiconductor material constituting the EML-LD, the group III-V semiconductor compound crystal such as InGaAsP epitaxially grown on an InP substrate is generally used. In this semiconductor material system, the energy gap difference, that is, the band discontinuity (ΔEg), is distributed in the ratio of 40:60 in the conduction band and the valence band at the heterointerface. Consequently, relatively large hole barrier ΔEv exists for the heavier holes 34. Thus, when carriers, that are, electrons and holes 34 are generated by absorbing high-intensity light in the multiple quantum well structure constituting the optical absorption layer, the heavier holes 34 are less likely to flow as a current beyond the relatively large hole barrier ΔEv on the valence band side than the lighter electrons. This phenomenon is called the hole pile-up phenomenon. When the hole pile-up phenomenon occurs, it becomes a factor that prevents high performance, such as degradation of high-speed response characteristics and a decrease in extinction ratio, due to the accumulated carriers shielding the external electric field (screening effect).

In particular, when the MQW layer is directly sandwiched by InP cladding layers having a relatively large bandgap energy, or when SCH layers made of InGaAsP are inserted between the MQW layer and the InP cladding layers, a large band discontinuity at the valence band edge, that is, the hole barrier ΔEv, exists at the heterointerface. As a result, the residence time for the holes 34 to exceed the hole barrier by thermal excitation and be absorbed by the InP cladding layer is increased.

One technical feature of the EML-LD, which is an example of the optical semiconductor device 100 according to Embodiment 1, is that heat generated by the absorbed light 28 that has absorbed the incident scattered light by 27 the lower scattered-light absorption layer 20 and the upper scattered-light absorption layer 22 is utilized in order to prevent the reduction of the extinction ratio due to the hole pile-up phenomenon.

In the optical modulator section 72, due to the heat generated by the light, that is, generated by the absorption of the scattered light 27, the magnitude of the electron barrier ΔEc on the conduction band side and the magnitude of the hole barrier ΔEv on the valence band side are reduced. Here, the electron barrier ΔEc and the hole barrier ΔEv are band discontinuities generated between the p-type InP upper first cladding layer 4 and the upper SCH layer 30b that is part of the light absorption layer 21 made of i-type InGaAsBi and is in contact with the p-type InP upper first cladding layer 4. Note that the same band discontinuities as in InGaAsP also exist in InGaAsBi.

As a result, even when high-intensity light is absorbed in the light absorption layer 21 made of i-type InGaAsBi and thus pairs of electrons and holes are generated, the hole barrier ΔEv on the valence band side is reduced more than where no heat is generated, so that the holes 34 easily flow as a current beyond the hole barrier ΔEv. That is, the influence of the hole pile-up phenomenon is reduced, thus providing an effect that the extinction ratio of the EML-LD is increased.

Furthermore, the advantage of adopting the light absorption layer 21 made of i-type InGaAsBi containing Be as the light absorption layer of the EML-LD will be described below.

The optical modulator section of the EML-LD formed above the InP substrate generally uses InGaAsP or AlGaInAs, which is a group III-V quaternary semiconductor compound crystal, as the semiconductor material constituting the light absorption layer. In this case, the change of the bandgap energy with respect to the ambient temperature fluctuation, that is, the temperature dependence of the bandgap energy is large. However, in order to achieve the desired characteristics in the optical modulator section, it is necessary to control the absorption spectrum in the order of several nm.

Consequently, in order to achieve the desired characteristics as an optical modulator section, a Peltier cooler, which is a temperature control mechanism, is usually installed to control the temperature at a constant level. As another method, there is also a method of mounting a mechanism for adjusting the bias voltage of the optical modulator section when the temperature changes. However, these additional mechanisms have problems such as an increase in power consumption, an increase in the complexity of the device structure, and an increase in the manufacturing cost. Consequently, as with the semiconductor laser section, if the optical modulator section can be operated in an uncooled state, the entire EML-LD can be operated in an uncooled state.

The light absorption layer 21 made of i-type InGaAsBi containing Be in the optical modulator section of the EML-LD enables the bandgap of InGaAsBi in the optical absorption layer to become almost constant with respect to temperature changes, so that changes in the optical absorption characteristics at low and high temperatures can be suppressed, thereby enabling the EML-LD to be operated in an uncooled state.

In the above description, as an example, the MQW layer 31, which is composed of the alternately stacked well layers 32 and barrier layers 33, the lower SCH layer 30a and the upper SCH layer 30b, which constitute the light absorption layer 21, are all composed of the group III-V semiconductor compound crystal containing Bi. However, a similar effect can also be achieved when only the lower SCH layer 30a and the upper SCH layer 30b are composed of the group III-V semiconductor compound crystal containing Bi. Other examples of the group III-V semiconductor compound crystals containing Bi include a group III-V quaternary semiconductor compound crystal made of InGaPBi and a group III-V pentagonal semiconductor compound crystal made of InGaPAsBi.

In the above description, the lower scattered-light absorption layer 20 and the upper scattered-light absorption layer 22 of the optical modulator section 72 are respectively provided so as to face the lower surface of the light absorption layer 21, that is, the surface on the n-type InP substrate 1 side, and the upper surface of the light absorption layer 21, that is, the surface on the surface side of the crystal growth layers. That is, a pair of the scattered-light absorption layers are provided. However, even when only one of the lower scattered-light absorption layer 20 or the upper scattered-light absorption layer 22 is provided, that is, even when the structure of the scattered-light absorption layer facing either the lower surface or the upper surface of the light absorption layer 21 is applied, it is also effective in reducing scattered light 27. In addition, applying such a structure also has the effect of simplifying the structure of optical semiconductor devices, thus providing an effect that an optical semiconductor device becomes easier to manufacture.

### Effect of Embodiment 1

As described above, in the optical semiconductor device according to Embodiment 1, the lower scattered-light absorption layer, which faces the lower surface of the light absorption layer made of i-type InGaAsBi, and the upper scattered-light absorption layer, which faces the upper surface of the light absorption layer, are each provided, and thus the scattering light that adversely affects the extinction ratio is absorbed and reduced. At the same time, the heat generated by the absorption of the scattering light is utilized to reduce the hole pile-up phenomenon, and thus the decrease in the extinction ratio caused by the pile-up phenomenon is also simultaneously suppressed by the synergistic effect, thus providing an effect of achieving an optical semiconductor device (EML-LD) having a high extinction ratio.

### Embodiment 2

### Configuration of Optical Semiconductor Device According to Embodiment 2

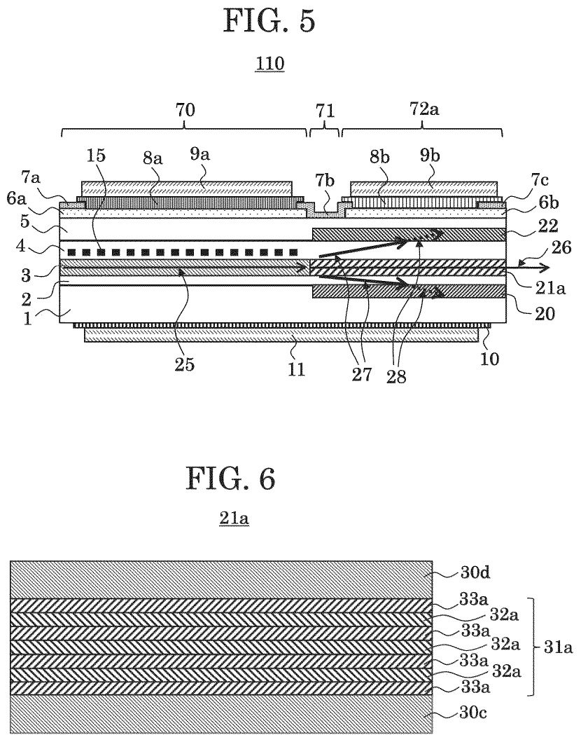

FIG. 5 is a cross-sectional view of an optical semiconductor device 110 according to Embodiment 2 along the optical waveguide direction. An EML-LD is described as an example of the optical semiconductor device 110 according to Embodiment 2.

The optical semiconductor device 110 according to Embodiment 2 is structurally different from the optical semiconductor device 100 according to Embodiment 1 in that, in the optical absorption layer 21a of the optical semiconductor device 110, only the well layer 32a of the MQW layer 31a contains Bi, whereas the barrier layer 33a, the lower SCH layer 30c, and the upper SCH layer 30d of the MQW layer 31a do not contain Bi. The other configurations are the same as those of the optical semiconductor device 100 according to Embodiment 1.

### Operation of Optical Semiconductor Device According to Embodiment 2

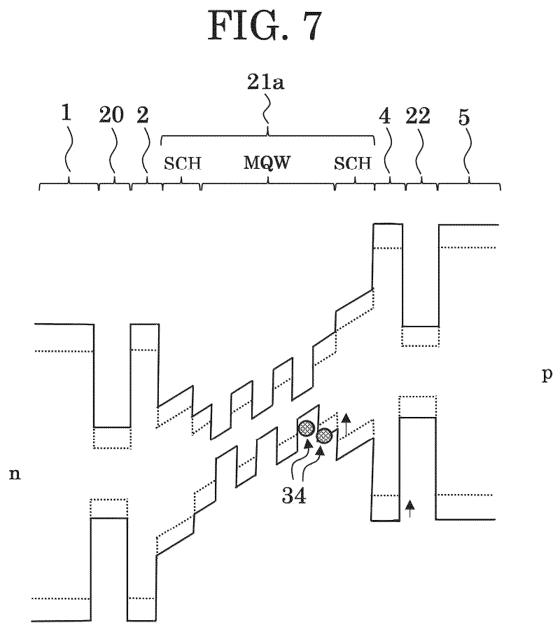

FIG. 7 is an energy band diagram of the optical modulator section 72a in the optical semiconductor device 110 according to Embodiment 2. As shown by the energy bands represented by the dotted lines in FIG. 7, the bandgap energies of the p-type InP upper first cladding layer 4, the upper scattered-light absorption layer 22, and the p-type InP upper second cladding layer 5 become smaller due to the heat generated by the absorption of the scattered light 27 than the energy bands represented by the solid lines in FIG. 7 when no heat is generated.

In the light absorption layer 21a, the bandgap energies of the barrier layer 33a of the MQW layer 31a, the lower SCH layer 30c, and the upper SCH layer 30d, which do not contain Bi, become smaller than the energy bands represented by the solid lines in FIG. 7 when no heat is generated. In contrast, since the well layer 32a contains Bi as described above, the temperature dependence of the bandgap energy thereof is small, so that the energy band thereof almost does not change even with the heat generated by the absorption of the scattered light 27.

As a result, the energy band of the well layer 32a almost does not change with the heat generated by the absorption of the scattered light 27, whereas the energy band of the barrier layer 33a is reduced, so that the hole barrier ΔEv between the well layer 32a and the barrier layer 33a is also reduced. Consequently, the holes 34 easily flows as a current beyond the hole barrier ΔEv. This means that the influence of the hole pile-up phenomenon is reduced, thus providing an effect that the extinction ratio of the EML-LD is increased.

In the above description, the case where only the well layer 32a of the MQW layer 31a, which is composed of alternately stacked well layers 32a and barrier layers 33a, constituting the light absorption layer 21a is made of the group III-V semiconductor compound crystal containing Bi is taken as an example. However, when not only the well layer 32a but only the barrier layer 33a is made of the group III-V semiconductor compound crystal containing Bi, the same effect can be achieved.

### Effect of Embodiment 2

As described above, in the optical semiconductor device according to Embodiment 1, the light absorption layer has the MQW layer in which only the well layers contain Bi, and the lower scattered-light absorption layer facing the lower surface of the light absorption layer and the upper scattered-light absorption layer facing the upper surface of the light absorption layer are provided. Therefore, the scattered light having an adverse effect on the extinction ratio is absorbed and reduced, and the heat generated by the absorption of the scattered light is utilized to reduce the pile-up phenomenon of holes between the well layers and the barrier layers which constitute the MQW layer, thereby simultaneously suppressing the reduction in the extinction ratio caused by the pile-up phenomenon, thus providing an effect of achieving an optical semiconductor device (EML-LD) having a high extinction ratio.

### Embodiment 3

### Configuration of Optical Semiconductor Device According to Embodiment 3

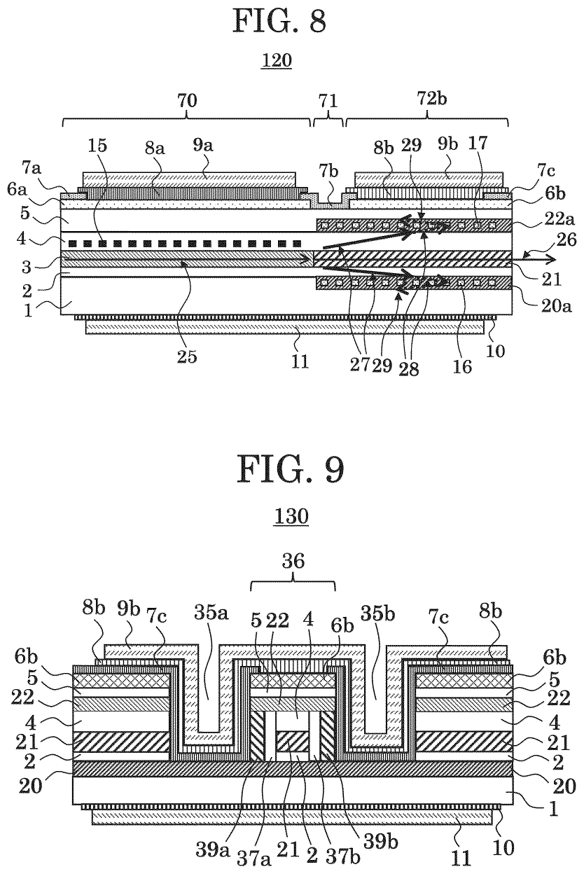

FIG. 8 is a cross-sectional view of the optical semiconductor device 120 according to Embodiment 3 along the optical waveguide direction. An EML-LD is given as an example of the optical semiconductor device 120 according to Embodiment 3.

The optical semiconductor device 120 according to Embodiment 3 is structurally different from the optical semiconductor device 100 according to Embodiment 1 in that the first-order diffraction grating 16 is provided in the lower scattered-light absorption layer 20a of the optical modulator section 72b of the optical semiconductor device 120, and the first-order diffraction grating 17 is provided in the upper scattered-light absorption layer 22a thereof. The other configurations are the same as those of the optical semiconductor device 100 according to Embodiment 1.

### Operation of Optical Semiconductor Device According to Embodiment 3

As described in Embodiment 1, in the EML-LD, generally, at the coupling section (separation section) between the semiconductor laser section configured by the DFB-LD and the optical modulator section configured by the EML, the scattered light that has not been guided into the light absorption layer of the optical modulator section from the laser light that has been incident from the semiconductor laser section is emitted from the output end surface of the optical modulator section and becomes leakage light. In the optical semiconductor device 100 according to Embodiment 1, the lower scattered-light absorption layer 20 and the upper scattered-light absorption layer 22 provided in the optical modulator section 72 function to absorb the scattered light 27 that has not been guided to the optical absorption layer 21 in the optical modulator section 72. However, particularly during high-power operation of the EML-LD, there may occur a case where the lower scattered-light absorption layer 20 and the upper scattered-light absorption layer 22 cannot completely absorb the scattered light 27.

In the optical semiconductor device 120 according to Embodiment 3, the first-order diffraction grating 16 provided in the lower scattered-light absorption layer 20a and the first-order diffraction grating 17 provided in the upper scattered-light absorption layer 22a function to prevent the scattered light 27 from being emitted from the output end surface of the optical modulator section 72 and becoming the leakage light by diffracting the unabsorbed scattered light 27 as diffracted light 29 heading in a direction other than the output end surface side of the optical modulator section 72. Consequently, the optical semiconductor device 120 according to Embodiment 3 has an effect of further reducing the leakage light emitted from the output end surface of the optical modulator section 72 to the outside.

In the above description, the structure in which the diffraction grating is provided in both the lower scattered-light absorption layer and the upper scattered-light absorption layer is taken as an example, but even when the first-order diffraction grating is provided only in either the lower scattered-light absorption layer or the upper scattered-light absorption layer, the effect of reducing the scattered light 27 can be achieved. Applying such a structure also has the effect of simplifying the structure of optical semiconductor devices, thus providing an effect that an optical semiconductor device becomes easier to manufacture.

### Effect of Embodiment 3

As described above, in the optical semiconductor device according to Embodiment 3, since the first-order diffraction gratings are respectively provided in the lower scattered-light absorption layer and the upper scattered-light absorption layer in the optical modulator section, the leakage light emitted from the output end surface of the optical modulator section to the outside can be further reduced compared with the optical semiconductor device according to Embodiment 1, thus providing an effect of achieving an optical semiconductor device having a higher extinction ratio.

### Embodiment 4

### Structure of Optical Semiconductor Device According to Embodiment 4

FIG. 9 is a cross-sectional view of the optical semiconductor device 130 according to Embodiment 4 in a direction perpendicular to the optical waveguide direction. An EML-LD is given as an example of the optical semiconductor device 130 according to Embodiment 4.

The optical semiconductor device 130 according to Embodiment 4 is structurally different from the optical semiconductor device 100 according to Embodiment 1 in that side scattered-light absorption layers 39a, 39b are respectively provided on the side surfaces of the mesa stripe 36 in the optical modulator section 72. The other configurations are the same as those of the optical semiconductor device 100 according to Embodiment 1.

That is, the optical modulator section 72 of the optical semiconductor device 130 according to Embodiment 4 includes the lower and upper scattered-light absorption layers 20, 22 provided to face the lower and upper surfaces of the light absorption layer 21, respectively, and the side scattered-light absorption layers 39a, 39b further provided on the side surfaces of the mesa stripe 36.

### Operation of Optical Semiconductor Device According to Embodiment 4

As described in Embodiment 1, in the EML-LD, generally, at the coupling section (separation section) between the semiconductor laser section configured by the DFB-LD and the optical modulator section configured by the EML, the scattered light that has not been guided into the light absorption layer of the optical modulator section from the laser light that has been incident from the semiconductor laser section becomes scattered light 27. The scattered light 27 has a component that propagates not only in the vertical direction of the light absorption layer 21 but also in the lateral direction of the stripe-shaped light absorption layer 21 in the mesa stripe 36, that is, in the direction toward the side surfaces of the mesa stripe 36.

In the optical semiconductor device 130 according to Embodiment 4, the side scattered-light absorption layers 39a, 39b are provided on the side surfaces of the mesa stripe 36 in the optical modulator section 72 to absorb the scattered light 27 that propagates in the lateral direction. As a result, it is possible to further reduce the leakage light emitted from the output end surface of the optical modulator section 72 to the outside.

### Effect of Embodiment 4

As described above, in the optical semiconductor device according to Embodiment 4, since the side scattered-light absorption layers are provided on the side surfaces of the mesa stripe in the optical modulator section, the leakage light emitted from the output end surface of the optical modulator section to the outside can be further reduced as compared with the optical semiconductor device according to Embodiment 1, thus providing an effect of achieving an optical semiconductor device having a higher extinction ratio.

In Embodiments 1 to 4, the group III-V semiconductor compound crystal containing Bi is exemplified as the semiconductor material constituting the light absorption layers 21, 21a, and have given InGaAsBi as an example. However, the light absorption layers 21, 21a may be made of a group III-V semiconductor compound crystal containing Sb (antimony). One example of the group III-V compound semiconductor crystal containing Sb is InGaAsSb.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 n-type InP substrate (semiconductor substrate)
2 n-type InP lower cladding layer (first-conductivity-type lower cladding layer)
3 active layer
4 p-type InP upper first cladding layer (second-conductivity-type upper cladding layer)
5 p-type InP upper second cladding layer
6a p-type InGaAs first contact layer
6b p-type InGaAs second contact layer
7a, 7b, 7c surface protection insulating film
8a p-side first electrode
8b p-side third electrode
9a p-side second electrode
9b p-side fourth electrode
10 n-side first electrode
11 n-side second electrode
15, 16, 17 diffraction grating
20, 20a lower scattered-light absorption layer
21, 21a light absorption layer
22, 22a upper scattered-light absorption layer
25 laser light
26 guided light
27 scattered light
28 absorbed light
29 diffracted light
30a, 30c lower SCH layer
30b, 30d upper SCH layer
31, 31a MQW layer
32, 32a well layer
33, 33a barrier layer
34 hole
35, 36 mesa stripe
35a, 35b mesa groove
37a, 37b high-resistivity InP buried layer
39a, 39b side scattered-light absorption layer
70 semiconductor laser section
71 separation section
72, 72a, 72b optical modulator section
100, 110, 120, 130 optical semiconductor device

1. An optical semiconductor device having a semiconductor laser section and an optical modulator section formed above a common semiconductor substrate, the optical semiconductor device comprising:
the semiconductor laser section including: a first-conductivity-type lower cladding layer; an active layer configured to emit laser light; and a second-conductivity-type upper cladding layer provided with a first-order diffraction grating, the lower cladding layer, the active layer and the upper cladding layer being each made of a group III-V semiconductor compound crystal; and
the optical modulator section including: a light absorption layer configured to absorb the laser light incident from the active layer, at least a part of the light absorption layer made of a group III-V semiconductor compound crystal containing Bi; and a scattered-light absorption layer that faces either a lower surface or an upper surface of the light absorption layer, or a pair of scattered-light absorption layers that face the lower surface and the upper surface of the light absorption layer, respectively, wherein
the optical modulator section has a mesa stripe including at least the light absorption layer and the scattered-light absorption layer, and side scattered-light absorption layers are provided on the side surfaces of the mesa stripe.

2. The optical semiconductor device according to claim 1, wherein
when the scattered-light absorption layer is provided on the lower surface side of the light absorption layer, the first-conductivity-type lower cladding layer is provided between the light absorption layer and the scattered-light absorption layer, and when the scattered-light absorption layer is provided on the upper surface side of the light absorption layer, the second-conductivity-type upper cladding layer is provided between the light absorption layer and the scattered-light absorption layer.

3.-12. (canceled)

13. An optical semiconductor device having a semiconductor laser section and an optical modulator section formed above a common semiconductor substrate, the optical semiconductor device comprising:
the semiconductor laser section including: a first-conductivity-type lower cladding layer; an active layer configured to emit laser light; and a second-conductivity-type upper cladding layer provided with a first-order diffraction grating, the lower cladding layer, the active layer and the upper cladding layer being each made of a group III-V semiconductor compound crystal; and
the optical modulator section including: a light absorption layer configured to absorb the laser light incident from the active layer, at least a part of the light absorption layer made of a group III-V semiconductor compound crystal containing Bi; and a scattered-light absorption layer that faces either a lower surface or an upper surface of the light absorption layer, or a pair of scattered-light absorption layers that face the lower surface and the upper surface of the light absorption layer, respectively, wherein
a first-order diffraction grating is provided in the scattered-light absorption layer.

14. The optical semiconductor device according to claim 13, wherein
when the scattered-light absorption layer is provided on the lower surface side of the light absorption layer, the first-conductivity-type lower cladding layer is provided between the light absorption layer and the scattered-light absorption layer, and when the scattered-light absorption layer is provided on the upper surface side of the light absorption layer, the second-conductivity-type upper cladding layer is provided between the light absorption layer and the scattered-light absorption layer.

15. An optical semiconductor device having a semiconductor laser section and an optical modulator section formed above a common semiconductor substrate, the optical semiconductor device comprising:
the semiconductor laser section including: a first-conductivity-type lower cladding layer; an active layer configured to emit laser light; and a second-conductivity-type upper cladding layer provided with a first-order diffraction grating, the lower cladding layer, the active layer and the upper cladding layer being each made of a group III-V semiconductor compound crystal; and
the optical modulator section including: a light absorption layer configured to absorb the laser light incident from the active layer, the light absorption layer including an MQW layer having alternately stacked well layers and barrier layers, a lower SCH layer formed on a lower surface of the MQW layer, and an upper SCH layer formed on an upper surface of the MQW layer, and the MQW layer, the lower SCH layer, and the upper SCH layer being each made of the group III-V semiconductor compound crystal containing Bi; and a scattered-light absorption layer that faces either a lower surface or an upper surface of the light absorption layer, or a pair of scattered-light absorption layers that face the lower surface and the upper surface of the light absorption layer, respectively.

16. The optical semiconductor device according to claim 15, wherein
when the scattered-light absorption layer is provided on the lower surface side of the light absorption layer, the first-conductivity-type lower cladding layer is provided between the light absorption layer and the scattered-light absorption layer, and when the scattered-light absorption layer is provided on the upper surface side of the light absorption layer, the second-conductivity-type upper cladding layer is provided between the light absorption layer and the scattered-light absorption layer.

17. An optical semiconductor device having a semiconductor laser section and an optical modulator section formed above a common semiconductor substrate, the optical semiconductor device comprising:
the semiconductor laser section including: a first-conductivity-type lower cladding layer; an active layer configured to emit laser light; and a second-conductivity-type upper cladding layer provided with a first-order diffraction grating, the lower cladding layer, the active layer and the upper cladding layer being each made of a group III-V semiconductor compound crystal; and
the optical modulator section including: a light absorption layer configured to absorb the laser light incident from the active layer, the light absorption layer including an MQW layer having alternately stacked well layers and barrier layers, a lower SCH layer formed on a lower surface of the MQW layer, and an upper SCH layer formed on an upper surface of the MQW layer, and only the lower SCH layer and the upper SCH layer being made of the group III-V semiconductor compound crystal containing Bi; and a scattered-light absorption layer that faces either a lower surface or an upper surface of the light absorption layer, or a pair of scattered-light absorption layers that face the lower surface and the upper surface of the light absorption layer, respectively.

18. The optical semiconductor device according to claim 17, wherein
when the scattered-light absorption layer is provided on the lower surface side of the light absorption layer, the first-conductivity-type lower cladding layer is provided between the light absorption layer and the scattered-light absorption layer, and when the scattered-light absorption layer is provided on the upper surface side of the light absorption layer, the second-conductivity-type upper cladding layer is provided between the light absorption layer and the scattered-light absorption layer.

19. The optical semiconductor device according to claim 17, wherein
the lower SCH layer and the upper SCH layer are made of InGaAsBi.

20. An optical semiconductor device having a semiconductor laser section and an optical modulator section formed above a common semiconductor substrate, the optical semiconductor device comprising:
the semiconductor laser section including: a first-conductivity-type lower cladding layer; an active layer configured to emit laser light; and a second-conductivity-type upper cladding layer provided with a first-order diffraction grating, the lower cladding layer, the active layer and the upper cladding layer being each made of a group III-V semiconductor compound crystal; and
the optical modulator section including: a light absorption layer configured to absorb the laser light incident from the active layer, the light absorption layer including an MQW layer having alternately stacked well layers and barrier layers, a lower SCH layer formed on a lower surface of the MQW layer, and an upper SCH layer formed on an upper surface of the MQW layer, and only the barrier layer being made of the group III-V semiconductor compound crystal containing Bi; and a scattered-light absorption layer that faces either a lower surface or an upper surface of the light absorption layer, or a pair of scattered-light absorption layers that face the lower surface and the upper surface of the light absorption layer, respectively.

21. The optical semiconductor device according to claim 20, wherein
when the scattered-light absorption layer is provided on the lower surface side of the light absorption layer, the first-conductivity-type lower cladding layer is provided between the light absorption layer and the scattered-light absorption layer, and when the scattered-light absorption layer is provided on the upper surface side of the light absorption layer, the second-conductivity-type upper cladding layer is provided between the light absorption layer and the scattered-light absorption layer.

22. The optical semiconductor device according to claim 20, wherein
the barrier layers are made of InGaAsBi.
